(19) United States
(12) Patent Application Publication
(10) Pub. No.: US 2010/0038456 A1
(43) Pub. Date: Feb. 18, 2010

(54) METHOD AND SYSTEM FOR SEPARATING A MULTIPLICITY OF CERAMIC COMPONENTS FROM A COMPONENT BLOCK

(76) Inventors: Christoph Hamann, Thalmassing (DE); Carsten Schuh, Baldham (DE)

Correspondence Address: King & Spalding LLP, 401 Congress Avenue, Suite 3200, Austin, TX, 78701, US

(21) Appl. No.: 12/594,409

(22) PCT Filed: Apr. 2, 2008
(86) PCT No.: PCT/EP2008/053941

§ 371 Date: Oct. 2, 2009

(30) Foreign Application Priority Data
Apr. 4, 2007 (DE) 10 2007 016 316.0

(51) Int. Cl. F02M 51/06; H01L 41/24; H01L 41/083; B28D 1/06

(52) U.S. Cl. 239/533.2; 29/25.35; 310/366; 125/12; 125/16.01; 123/456; 123/472

(57) ABSTRACT

In a method for detaching a plurality of ceramic components (11-15) from a ceramic component block (1), the following steps are provided: providing the component block (1); mounting a plurality of parallel wire segments (21-26) in a frame (3) to form a saw frame (2); and sawing the provided component block (1) into the plurality of components (11-15) using the saw frame (2).

### CROSS-REFERENCE TO RELATED APPLICATIONS

This application is a U.S. National Stage Application of International Application No. PCT/EP2008/053941 filed Apr. 2, 2008, which designates the United States of America, and claims priority to German Application No. 10 2007 016 316.0 filed Apr. 4, 2007, the contents of which are hereby incorporated by reference in their entirety.

### TECHNICAL FIELD

The invention relates to a method and system for separating a multiplicity of ceramic components from a component block.

### BACKGROUND

Ceramic components are, for example, piezo stacks employed in the production of piezo actuators.

A piezo actuator consists generally of a plurality of piezoceramic plates. A piezoceramic is a material that expands owing to the piezoelectric effect when an electric voltage is applied. Piezoceramics of said type form the basis of the piezo actuators which travel a distance of a few micrometers when a voltage is applied.

The piezoceramics are employed as, for instance, base bodies of piezo actuators whose fields of application include the motor-vehicle domain where they are used as, for example, electromagnetic transducers in common-rail injection systems for internal-combustion engines.

The above-described piezoceramics are individually furnished on both sides with metallic electrodes or, as the case may be, inner electrodes. When a voltage is applied to said inner electrodes, the piezoceramic reacts in the form a lattice distortion which results along the main axis in the useful linear expansion already explained above. Because, though, said expansion is less than 2 per mil of the layer thickness along the main axis, a correspondingly greater layer thickness of active piezoceramics has to be provided to achieve a desired absolute linear expansion. However, an increase in the layer thickness of the individual piezoceramic layers within a piezo actuator is accompanied by an increase in the voltage necessary for operating the piezo actuator. To keep said voltage within manageable limits, the thickness of individual piezo layers in multi-layer actuators is usually between 20 μm and 200 μm. A piezo actuator must therefore have a suitable number of individual ceramic layers for a desired linear expansion, for example.

The applicant is aware of stacking, for example, piezoceramic green films alternating with inner-electrode material for producing piezo stacks.

The applicant is further aware in-house of fabricating the piezo stacks in multiple printed panels by stacking then pressing together a multiplicity of “green”, non-sintered ceramic films or piezoceramic green films or piezo layers. Said stack then needs to be isolated or separated into a multiplicity of individual components.

The applicant is aware in-house of a wire-saw technique for performing said isolating or separating. Individual piezo stacks can be fashioned from the green block or component block with the aid of said wire-saw technique. Diamond-tipped saw wires can in particular be used therein. Said saw wire is mounted onto two winding coils and wound back accordingly in the course of separation cutting. That means, however, that a long wire length of 10 m and more, depending on the machine employed, actively participates in the sawing process. The machine employed is hence correspondingly complex in structure and the saw wire will be subjected to a mechanically heavy load owing to the necessary deflecting and tensioning rollers, a factor that will shorten the useful life of the saw wire used and so increase the costs correspondingly.

### SUMMARY

According to various embodiments, the ceramic components can be isolated simply and in particular economically.

According to further embodiments, a method and system for isolating or separating the multiplicity of ceramic components from a ceramic component block can be provided, which method and system will extend the useful life of the saw wire used.

According to yet further embodiments, a method and system for separating or isolating a multiplicity of ceramic components from a ceramic component block can be provided, which method and system are independent of the cross-sectional shape of the piezo stacks requiring to be produced.

According to an embodiment, a method for separating a multiplicity of ceramic components from a ceramic component block, may have the steps: Providing the component block; clamping a multiplicity of parallel wire segments into position in a frame for embodying a saw frame; and sawing the component block that has been provided into the multiplicity of components using the saw frame.

According to a further embodiment, two wire clamps can be arranged mutually opposite on the frame for each wire segment requiring to be clamped into position, by means of which clamps the respective wire segment is clamped into position. According to a further embodiment, a pre-defined wire tension can be set by means of the wire clamps for the respective wire segment clamped into position. According to a further embodiment, the wire clamp can be spring-mounted by means of a spring device. According to a further embodiment, whenever a pre-defined wear limit has been reached for the wire segments clamped into position in the frame, a new wire segment will be clamped into position in the frame by feeding out a wire from a supply roll, or the saw frame will be replaced. According to a further embodiment, the saw frame can be moved when the component block that has been provided is sawn. According to a further embodiment, the component block can be embodied as a stack in which a multiplicity of piezoceramic green films are arranged alternating with an inner-electrode material. According to a further embodiment, the ceramic component can be embodied as a piezo stack in which are arranged a multiplicity N of first inner electrodes and a multiplicity N of second inner electrodes, with a piezoceramic green film being arranged between a first inner electrode and a second inner electrode and the multiplicity N of first inner electrodes being contactable with a first outer electrode and the multiplicity N of second inner electrodes being contactable with a second outer electrode.

According to another embodiment, a system for separating the multiplicity of ceramic components from a ceramic component block, may have a saw frame having a multiplicity of parallel wire segments clamped into position in a frame; and an actuator that drives the saw frame for sawing the component block into the multiplicity of components.

According to a further embodiment, for each wire segment requiring to be clamped into position the frame may have two mutually opposite wire clamps that clamp the respective wire segment into position. According to a further embodiment, the wire clamp may have a setting device which sets a pre-defined wire tension for the wire segment clamped into position. According to a further embodiment, a spring device can be provided for at least one wire clamp, on which device the wire clamp is spring-mounted. According to a further embodiment, a feed device can be provided which feeds out a new wire segment of a wire from a supply roll whenever a pre-defined wear limit has been reached for the wire segments clamped into position in the frame.

According to yet another embodiment, a piezo-actuator may have a piezo stack that has been produced in keeping with the method as described above.

According to yet another embodiment, an injection system for injecting fuel under a pre-defined fuel pressure may have a piezo actuator as described above which is suitable for raising and lowering an injector needle that opens and closes an injector by means of which the fuel is injected.

### BRIEF DESCRIPTION OF THE DRAWINGS

The invention is explained in more detail below with the aid of the exemplary embodiments shown in the schematics:

FIG. 1 is a schematic block diagram of a first exemplary embodiment of a system for separating the multiplicity of ceramic components from a ceramic component block;

FIG. 2 is a schematic block diagram of a second exemplary embodiment of a system for separating the multiplicity of ceramic components from a ceramic component block;

FIG. 3 is a schematic flowchart of an exemplary embodiment of the method for separating the multiplicity of ceramic components from a ceramic component block; and

FIG. 4 is a schematic block diagram of a piezo stack that has been produced in keeping with the method shown in FIG. 3.

Unless indicated otherwise, elements and devices that are physically or functionally identical have been assigned the same reference numerals in all figures.

### DETAILED DESCRIPTION

What is accordingly proposed according to various embodiments, is a method for separating a multiplicity of ceramic components from a ceramic component block, which method comprises the following steps:
Providing the component block or green block;
clamping a multiplicity of parallel wire segments or wire sections into position in a frame for embodying a saw frame; and
sawing the component block that has been provided into the multiplicity of components using the saw frame.

Further proposed is a system for separating the multiplicity of ceramic components from a ceramic component block, which system has:
a saw frame that has a multiplicity of parallel wire segments clamped into position in a frame; and
an actuator that drives or moves the saw frame for sawing the component block into the multiplicity of components.

A particular advantage is that the use of a multiplicity of saw wires or wire segments or wire sections having a fixed, predefined spacing that corresponds to the grid pitch of the individual piezo stacks in the green block or component block will enable a plurality of piezo stacks to be processed in parallel and allow separating from the printed panel or multiple printed panel to be performed correspondingly efficiently. The present invention will hence provide a simple and particularly also economical possibility of isolating the ceramic components.

Use of the saw frame will furthermore also enable the piezo stacks to have any cross-sectional shape, for example round, rectangular, hexagonal, or oval, or suchlike. That would be precluded by a conventional separating method such as one employing saw blades or the wire-saw technique.

According an embodiment, the mechanical and thermal load on the already separated lateral surfaces of the piezo stacks due to the friction of the saw wire is furthermore very low, there is no top-surface smudging, and no pressure is put on the saw wire or, as the case may be, wire segment by thermal expansion of the block material. The useful life of the wire segments used will hence be substantially extended.

According an embodiment, two wire clamps are arranged mutually opposite on the frame for each wire segment requiring to be clamped into position, by means of which clamps the respective wire segment is clamped into position.

According an embodiment, a pre-defined wire tension is set by means of the wire clamps for the respective wire segment clamped into position.

According an embodiment, the wire clamp is spring-mounted by means of a spring device.

According to an embodiment, whenever a pre-defined wear limit has been reached for the wire segments clamped into position in the frame, a new wire segment will be clamped into position in the frame by feeding out a wire from a supply roll, or the saw frame will be replaced.

According to a further embodiment, the saw frame is moved when the component block that has been provided is sawn. That will obviate the need for any angle, deflecting, or tensioning rollers so that separating or isolating will be more economical and the saw wire will consequently furthermore be subject to less wear. The cost of isolating or separating will be further reduced as a result.

According to a further embodiment, the component block is embodied as a stack in which a multiplicity of piezoceramic green films or ceramic green films or piezo layers are arranged alternating with an inner-electrode material.

According to a further embodiment, the ceramic component is embodied as a piezo stack in which are arranged a multiplicity N of first inner electrodes and a multiplicity N of second inner electrodes, with a piezoceramic green film being arranged between a first inner electrode and a second inner electrode and the multiplicity N of first inner electrodes being contactable with a first outer electrode and the multiplicity N of second inner electrodes being contactable with a second outer electrode.

In a further development, for each wire segment requiring to be clamped, the frame has two mutually opposite wire clamps that clamp the respective wire segment into position.

According to a further development, the wire clamp has a setting device which sets a pre-defined wire tension for the wire segment clamped into position.

According to a further development, a spring device is provided for at least one wire clamp, on which device the wire clamp is spring-mounted. A separate spring device is preferably provided for each wire clamp.

According to a further development, a feed device is provided.

The feed device feeds out a new wire segment for clamping into position in the frame if a pre-defined wear limit has been reached for the wire segments clamped into position in the frame and used hitherto.

Further proposed is a piezo actuator having a piezo stack, with the piezo stack having been produced in keeping with the above-explained method.

Further proposed is an injection system for injecting fuel under a pre-defined fuel pressure, with the injection system having a piezo actuator as explained above which is suitable for raising and lowering an injector needle that opens and closes an injector by means of which the fuel is injected.

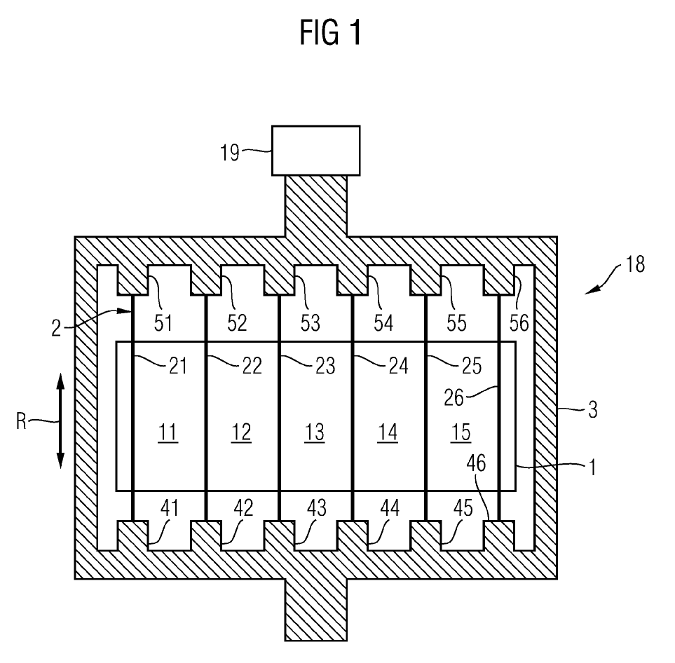

FIG. 1 is a schematic block diagram of a first exemplary embodiment of a system 18 for separating the multiplicity of ceramic components 11-15 from a ceramic component block 1. The system 18 has a saw frame 2 and an actuator 19. The saw frame 2 has a multiplicity of parallel wire segments 21-26 clamped into position in a frame 3. The actuator 19 drives the saw frame 2 for sawing the component block 1 into the multiplicity of components 11-15 or, as the case may be, moves said frame. The reference letter R in FIG. 1 therein shows the sawing direction. Six wire segments 21-26 are shown in FIG. 1 without loss of generality. Any number of wire segments 21-26 can, though, be clamped into position in the frame 3. Further shown in FIG. 1 is a component block 1 or green block that is cuboidal in shape. That shape for the green block or component block is also only exemplary; any other shapes are also conceivable.

For each wire segment 21-26 requiring to be clamped into position the frame 3 preferably has two mutually opposite wire clamps 41-46; 51-56 that clamp the respective wire segment 11-15 into position. For example the mutually opposite wire clamps 41 and 51 clamp the wire segment 21 into position.

The wire clamp 41-46; 51-56 preferably has a setting device (not shown) which sets a pre-defined wire tension for the wire segment 21-26 that has been clamped into position.

In particular a spring device (not shown) is provided for at least one wire clamp 41-46; 51-56. In particular a separate spring device can be provided for each wire clamp 41-46; 51-56. The respective wire clamp 41-46; 51-56 is spring-mounted on the spring device.

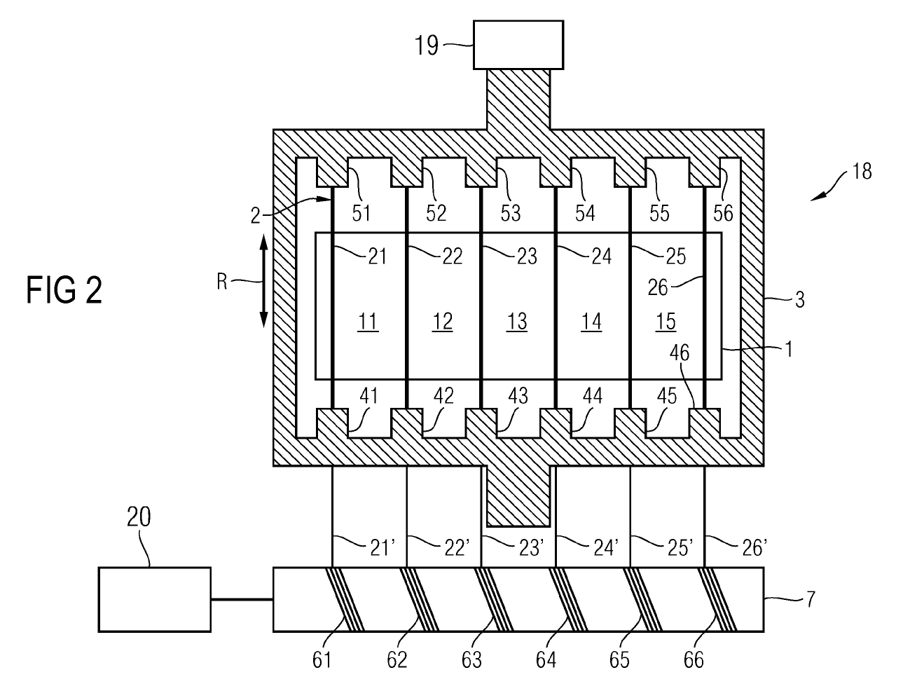

FIG. 2 is a schematic block diagram of a second exemplary embodiment of a system 18 for separating the multiplicity of ceramic components 11-15 from a ceramic component block 1. The second exemplary embodiment shown in FIG. 2 has all the features of the first exemplary embodiment shown in FIG. 1 and a feed device 20 as well as a supply roll 7.

The feed device 20 is suitable for feeding out a new wire segment 21′-26′ of a wire 61-66 from a supply roll 7 whenever a pre-defined wear limit has been reached for the wire segments 21-26 clamped into position in the frame 3 so that the wire segments 21-26 hitherto clamped into position will be replaced by the new wire segments 21′-26′. The wire segments 21-26 or, as the case may be, the new wire segments 21′-26′ or, as the case may be, the wires 61-66 are embodied in particular as diamond-tipped saw wires.

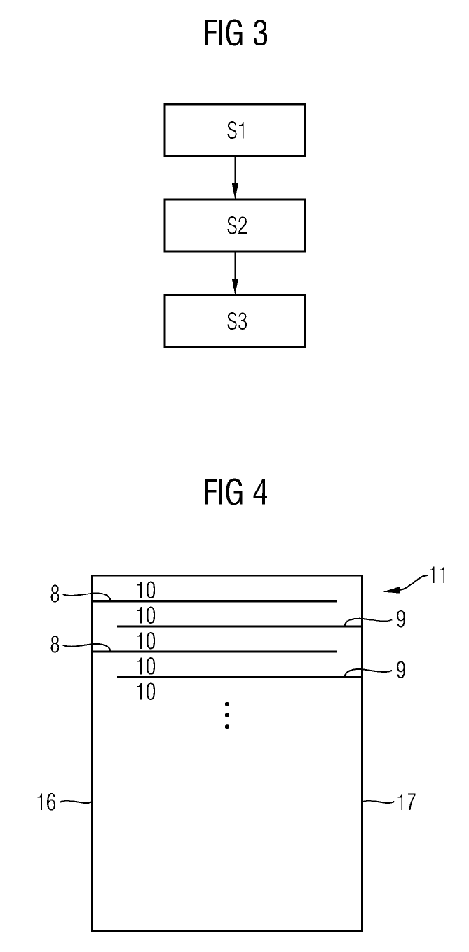

FIG. 3 is a schematic flowchart of an exemplary embodiment of the method for separating a multiplicity of ceramic components 11-15 from a ceramic component block 1. The method according to various embodiments is explained below with the aid of the flowchart in FIG. 3, with reference made to the block diagrams in FIGS. 1 and 2. The method has the following steps S1-S3:

### Step S1 of the Method:

A component block 1 or green block is provided. The component block 1 is embodied as, for instance, a stack in which a multiplicity of piezoceramic green films are arranged alternating with an inner-electrode material.

### Step S2 of the Method:

A multiplicity of parallel wire segments 21-26 or wire sections are clamped into position in a frame 3 for embodying a saw frame 2. In particular two mutually opposite wire clamps 41-46; 51-56 are therein arranged on the frame 3 for each wire segment 21-26 requiring to be clamped into position. The respective wire segment 21-26 is clamped into position by means of the respectively opposite wire clamps 41-46; 51-56.

A pre-defined wire tension is preferably set by means of the wire clamp 41-46; 51-56 for the respective wire segment 21-26 clamped into position. The respective wire clamp 41-46; 51-56 is preferably spring-mounted by means of a spring device.

### Step S3 of the Method:

The component block 1 that has been provided is sawn into the multiplicity of components 11-15 using the saw frame 2. Whenever a pre-defined wear limit has been reached for the wire segments 21-26 clamped into position in the frame 3, preferably a new wire segment 21′-26′ will be clamped into position in the frame 3 by feeding out a wire 61-66 from a supply roll 7. The entire saw frame 2 can alternatively also be replaced or clamped into position in said new wire segment 21′-26′.

The ceramic component 11-15 is embodied in particular as a piezo stack. FIG. 4 is accordingly a schematic block diagram of a piezo stack 11 of such type. The piezo stack 11 has in particular a multiplicity N of first inner electrodes 8 and a multiplicity N of second inner electrodes 9. A piezoceramic green film 10 or piezo layer is furthermore arranged between a first inner electrode 8 and a second inner electrode 9. It is furthermore preferable for the multiplicity N of first inner electrodes 8 to be contactable with a first outer electrode 16 and for the multiplicity of second inner electrodes 9 to be contactable with a second outer electrode 17.

Although described above using the preferred exemplary embodiments, the present invention is not limited thereto but open to multifarious modifications. For example the invention can conceivably be applied not only to piezo stacks of monolithic multilayer design as in the exemplary embodiments shown in the figures but to any piezo actuators.

What is claimed is:

1. A method for separating a multiplicity of ceramic components from a ceramic component block, comprising the steps:
Providing the component block;
clamping a multiplicity of parallel wire segments into position in a frame for embodying a saw frame; and
sawing the component block that has been provided into the multiplicity of components using the saw frame.

2. The method according to claim 1, wherein
two wire clamps are arranged mutually opposite on the frame for each wire segment requiring to be clamped into position, by means of which clamps the respective wire segment is clamped into position.

3. The method according to claim 2, wherein
a pre-defined wire tension is set by means of the wire clamps for the respective wire segment clamped into position.

4. The method according to claim 2, wherein
the wire clamp is spring-mounted by means of a spring device.

5. The method according to claim 1, wherein
whenever a pre-defined wear limit has been reached for the wire segments clamped into position in the frame, a new wire segment will be clamped into position in the frame by feeding out a wire from a supply roll, or the saw frame will be replaced.

6. The method according to claim 1, wherein
the saw frame is moved when the component block that has been provided is sawn.

7. The method according to claim 1, wherein
the component block is embodied as a stack in which a multiplicity of piezoceramic green films are arranged alternating with an inner-electrode material.

8. The method according to claim 1, wherein
the ceramic component is embodied as a piezo stack in which are arranged a multiplicity N of first inner electrodes and a multiplicity N of second inner electrodes, with a piezoceramic green film being arranged between a first inner electrode and a second inner electrode and the multiplicity N of first inner electrodes being contactable with a first outer electrode and the multiplicity N of second inner electrodes being contactable with a second outer electrode.

9. A system for separating the multiplicity of ceramic components from a ceramic component block, comprising:
a saw frame having a multiplicity of parallel wire segments clamped into position in a frame; and
an actuator that drives the saw frame for sawing the component block into the multiplicity of components.

10. The system according to claim 9, wherein
for each wire segment requiring to be clamped into position the frame has two mutually opposite wire clamps that clamp the respective wire segment into position.

11. The system according to claim 10, wherein
the wire clamp has a setting device which sets a pre-defined wire tension for the wire segment clamped into position.

12. The system according to claim 10, wherein
a spring device is provided for at least one wire clamp, on which device the wire claim is spring-mounted.

13. The system according to claim 10, wherein
a feed device is provided which feeds out a new wire segment of a wire from a supply roll whenever a pre-defined wear limit has been reached for the wire segments clamped into position in the frame.

14. A piezo-actuator having a piezo stack that has been produced according to the method as claimed in claim 8.

15. An injection system for injecting fuel under a pre-defined fuel pressure having a piezo actuator according to claim 14 which is suitable for raising and lowering an injector needle that opens and closes an injector by means of which the fuel is injected.

16. A system for separating a multiplicity of ceramic components from a ceramic component block, comprising:
a saw frame for clamping a multiplicity of parallel wire segments into position; and
means for sawing the component block into the multiplicity of components using the saw frame.

17. The system according to claim 16, wherein
two wire clamps are arranged mutually opposite on the frame for each wire segment requiring to be clamped into position, by means of which clamps the respective wire segment is clamped into position.

18. The system according to claim 17, wherein
a pre-defined wire tension is set by means of the wire clamps for the respective wire segment clamped into position.

19. The system according to claim 17, wherein
the wire clamp is spring-mounted by means of a spring device.

20. The system according to claim 16, wherein
whenever a pre-defined wear limit has been reached for the wire segments clamped into position in the frame, a new wire segment will be clamped into position in the frame by feeding out a wire from a supply roll, or the saw frame will be replaced.
